(19) United States
(12) Patent Application Publication
(10) Pub. No.: US 2006/0273382 A1
(43) Pub. Date: Dec. 7, 2006

(54) High density trench MOSFET with low gate resistance and reduced source contact space

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: M-MOS Sdn. Bhd.

(21) Appl. No.: 11/204,860

(22) Filed: Aug. 15, 2005

Related U.S. Application Data
(63) Continuation-in-part of application No. 11/147,075, filed on Jun. 6, 2005.

(51) Int. Cl. H01L 29/78; H01L 21/336

(52) U.S. Cl. 257/330; 257/382; 438/589; 438/270

(57) ABSTRACT

A trenched metal oxide semiconductor field effect transistor (MOSFET) device that includes gate contact trenches and source contact trenches opened through oxide insulation layers into the gate polysilicon and the body-source silicon regions. The gate contact trenches and the source contact trenches are filled with gate contact plug and source contact plug for electrically contacting the gate poly and the source-body regions such that the gate resistance is reduced and narrower source contact areas are achieved.

This Patent application is a Continuation in Part (CIP) Application of a co-pending application Ser. No. 11/147,075 filed by a common Inventor of this Application on Jun. 6, 2005. The Disclosures made in that Application including the drawings and descriptions are hereby incorporated by reference.

### BACKGROUND OF THE INVENTION

1. Field of the Invention

This invention relates generally to the cell structure, device configuration and fabrication process of power semiconductor devices. More particularly, this invention relates to a novel and improved cell structure, device configuration and improved process for fabricating a trenched semiconductor power device with reduce gate resistance.

2. Description of the Prior Art

Conventional technologies of forming gate contact and gate runners for high density trenched MOSFET devices are faced with a technical difficulty of poor metal step coverage that leads to unreliable electrical contact, and high gate resistance when the cell pitch is shrunken. The technical difficulty is especially pronounced when a metal oxide semiconductor field effect transistor (MOSFET) cell density is increased above 200 million cells per square inch (200 M/in²) with the cell pitch reduced to 1.8 um or to even a smaller dimension. The trench width has been reduced below 0.4 um, causing high gate resistance (Rg) as result of less doped poly in trench area. These poor contacts and high gate resistance adversely affect the device performance, and the product reliability is also degraded.

For the purpose of reducing the gate resistance, several gate structures and gate material have been disclosed. Specifically, in U.S. Pat. No. 6,737,323, Mo discloses a trench MOSFET shown in FIG. 1A that includes trenched gates that are substantially filled with high-conductivity material such as refractory metal particularly suitable for fast switching trench MOSFET applications. The trench is first lined by forming a dielectric material such as silicon dioxide covering the walls of the trenches. A layer of polysilicon is then formed on the dielectric material and provides buffering for stress relief. The trench is then filled substantially with refractory metal such as tungsten. This MOSFET device, as that shown in FIG. 1A, has several limitations. First, the planar source contacts occupy more space and thus prevent further shrinking of dimension of the device. Furthermore, the P-body regions are formed before the trench is filled with the refractory metal because the refractory metal is not able to tolerate a P-body diffusion process that requires high temperature, e.g., 1050 C, applied to the device. The high temperature causes punch-through issue as result of segregation of P-body boron near channel region into sacrificial and gate oxidations. The effect of punch-through becomes pronounced when cell density higher above 200 M/in².

Further improvements are made in another U.S. Pat. No. 6,849,899 wherein Hshieh et al. disclose a method for making trench DMOS as shown FIG. 1B, that utilizes polycide and refractory techniques to make trench DMOS for the purpose of achieving low gate resistance, low gate capacitance, reduced distributed RC gate propagation delay, and improved switching speeds for high frequency applications. FIG. 1B is a cross sectional view of this prior art DMOS device. Again, there are still the same limitations and difficulties that the planar source contact occupies greater space and further the punch-through issues still limit the performance of the device as that encountered in the other conventional MOSFET devices.

Therefore, a need still exists in the art of the semiconductor device fabrication, particularly for trenched power MOSFET design and fabrication, to provide a novel cell structure, device configuration and fabrication process that would resolve these difficulties and design limitations. Specifically, it is desirable to reduce the space occupied by the source contact and meanwhile to reduce the gate resistance. Additionally, it is required to overcome the problems of poor metal step coverage of the gate contact metal especially for gate contact openings that has high aspect ratio and the size of the transistor cells are significantly reduced to increase the cell density of a trenched semiconductor power device.

### SUMMARY OF THE PRESENT INVENTION

It is therefore an object of the present invention to provide new and improved cell configuration and new processes to form a trenched semiconductor device, specifically, a trenched MOSFET device that is able to overcome the above discussed technical difficulties and limitations.

In one aspect of this invention, the MOSFET includes gate contact trenches and source contact trenches opened through oxide insulation layers into the gate polysilicon and the body-source silicon regions. The gate contact trenches and the source contact trenches are filled with gate contact plug and source contact plug for electrically contacting the gate poly and the source-body regions such that the gate resistance is reduced and narrower source contact areas are achieved.

Another aspect of this invention is that the Ti/TiN/W plugs filled in the gate contact trenches and the source contact trenches are formed at the same time in all areas including the active and the termination areas to provide good metal step coverage over the metal contact. The good metal contacts are established for critical dimension smaller than 0.5 micrometers whereby the contact space requirements are reduced. Better gate resistance is also achieved for high cell density MOSFET device because of better metal contact without the metal step coverage problems of the conventional technology.

A further aspect of this invention is a reduce gate resistance is achieved without requiring the gate runners in the active areas. The gate contact plug filled in the gate contact trenches provide better contact to the gate polysilicon with the bottom or the gate contact plug extends into the trenched gate polysilicon.

Another aspect of this invention is to form the P-body after the formation of the trenches thus eliminates the punch through problem frequently occurs to the conventional MOSFET devices.

Briefly, in a preferred embodiment, the present invention discloses a trenched metal oxide semiconductor field effect transistor (MOSFET) device that includes a trenched gate surrounded by a source region encompassed in a body region above a drain region disposed on a bottom surface of a substrate. The MOSFET device further includes at least two contact trenches opened through an insulation layer covering the MOSFET device wherein the contact trenches extending into the trenched gate and the body region and filled with a gate contact plug and a source contact plug for electrically contact respectively to a gate metal and a source metal disposed on top of the insulation layer. In a preferred embodiment, the gate contact trench and source contact trench filled with a Ti/TiN barrier layer and a tungsten plug to form the gate contact plug and the source contact plug. In another preferred embodiment, the gate contact trench is opened through an oxide layer as the insulation layer and penetrating into the trenched gate filled with a gate polysilicon. The source contact trench is opened through the oxide layer as the insulation layer and penetrating into the body region composed of a doped silicon disposed near a top surface of the substrate. In another preferred embodiment, the gate contact trench and the source contact trench are opened by a dry oxide etch process followed by a silicon etch to form substantially vertical trenches to extend to the trenched gate and the body region. In another preferred embodiment, the gate contact trench and the source contact trench are opened by a dry oxide etch process followed by a silicon etch to form substantially vertical trenches with stepwise side walls to extend to the trenched gate and the body region. In another preferred embodiment, the gate contact trench and the source contact trench are opened by a dry oxide etch process followed by a silicon etch to form trenches with sloped side walls to extend to the trenched gate and the body region. In another preferred embodiment, the gate contact trench and the source contact trench are opened by a dry oxide etch process with an nitride spacer followed by a silicon etch to form substantially champagne-cup shaped trenches with stepwise side walls to extend to the trenched gate and the body region. In another preferred embodiment, the gate contact plug electrically contacting the trenched gate via a bottom portion of the gate contact plug contact the trenched gate and the source contact plug electrically contacting the source region via side-walls of the source contact trench extending into the body region. In another preferred embodiment, the gate contact plug electrically contacting sidewalls of the gate contact trench extending into the trenched gate. In another preferred embodiment, the trenched MOSFET device further includes a thin resistance reduction layer formed on top of the gate contact plug and the source contact plug for providing greater contacting areas to the gate contact plug and the source contact plug. In another referred embodiment, the trenched MOSFET device further includes a thin resistance reduction layer composed of Ti disposed on top of the gate contact plug and the source contact plug for providing greater contacting areas to the gate contact plug and the source contact plug. In another preferred embodiment, the trenched MOSFET device further includes a thin resistance reduction layer composed of Ti/TiN disposed on top of the gate contact plug and the source contact plug for providing greater contacting areas to the gate contact plug and the source contact plug. In another preferred embodiment, the trenched MOSFET device further includes a thick front metal layer disposed on top of the resistance-reduction layer for providing a contact layer for a wire or wireless bonding package. In another preferred embodiment, the front thick metal layer includes an aluminum layer. In another preferred embodiment, the front thick metal layer includes an AlCu layer. In another preferred embodiment, the front thick metal layer includes an AlCuSi layer. In another preferred embodiment, the front thick metal layer includes an Al/NiAu layer. In another preferred embodiment, the front thick metal layer includes an AlCu/NiAu layer. In another preferred embodiment, the front thick metal layer includes an AlCuSi/NiAu layer. In another preferred embodiment, the front thick metal layer includes a NiAg layer. In another preferred embodiment, the front thick metal layer includes a NiAu layer. In another preferred embodiment, the MOSFET cell further includes a N-channel MOSFET cell. In another preferred embodiment, the MOSFET cell further includes a P-channel MOSFET cell.

This invention further discloses a method for manufacturing a trenched metal oxide semiconductor field effect transistor (MOSFET) device. The method includes a step of forming the MOSFET device with a trenched gate surrounded by a source region encompassed in a body region above a drain region disposed on a bottom surface of a substrate. The method further includes a step of opening at least two contact trenches through an insulation layer covering the MOSFET device and extending the contact trenches into a trenched gate and a body region followed by filling the contact trenches with a gate contact plug and a source contact plug for electrically contacting respectively to a gate metal and a source metal disposed on top of the insulation layer. In a preferred embodiment, the step of filling the contact trenches further includes a step of filling the gate contact trench and source contact trench with a Ti/TiN barrier layer and a tungsten plug to form the gate contact plug and the source contact plug. In another preferred embodiment, the step of opening the contact trenches further includes a step of opening a gate contact trench through an oxide layer as the insulation layer for penetrating into a gate polysilicon filled in the trenched gate. The step of opening the contact trenches further includes a step of opening a source contact trench is through the oxide layer as the insulation layer for penetrating into the body region composed of a doped silicon disposed near a top surface of the substrate. In another preferred embodiment, the step of opening the gate contact trench and the source contact trench further includes a step of applying a dry oxide etch process followed by a silicon etch to form substantially vertical trenches to extend to the trenched gate and the body region. In another preferred embodiment, the step of opening the gate contact trench and the source contact trench further includes a step of applying a dry oxide etch process followed by a silicon etch to form substantially vertical trenches with stepwise side walls to extend to the trenched gate and the body region. In another preferred embodiment, the step of opening the gate contact trench and the source contact trench further includes a step of applying a dry oxide etch process followed by a silicon etch to form trenches with sloped side walls to extend to the trenched gate and the body region. In another preferred embodiment, the step of opening the gate contact trench and the source contact trench further includes a step of applying a dry oxide etch process with an nitride spacer followed by a silicon etch to form substantially champagne-cup shaped trenches with stepwise side walls to extend to the trenched gate and the body region. In another preferred embodiment, the step of filling contact trenches with the gate contact plug for electrically contacting the trenched gate further includes a step of filling the contact trenches with the gate contact plug for electrically contacting the trenched gate via a bottom portion of the gate contact plug and the step of filling contact trenches with the source contact plug for electrically contacting the source further includes a step of filling the contact trenches with the source contact plug for electrically contacting the source via side-walls of the source contact trench extending into the body region. In another preferred embodiment, the step of filling the contact trenches with the gate contact plug further includes a step of filling the gate contact plug to extend into the trench gate for electrically contacting the gated trench via side walls of the gate contact trench extending into the trenched gate. In another preferred embodiment, the method further includes a step of forming a thin resistance reduction layer on top of the gate contact plug and the source contact plug for providing greater contacting areas to the gate contact plug and the source contact plug. In another preferred embodiment, the method further includes a step of forming a thin resistance reduction layer composed of Ti on top of the gate contact plug and the source contact plug for providing greater contacting areas to the gate contact plug and the source contact plug. In another preferred embodiment, the method further includes a step of forming a thin resistance reduction layer composed of Ti/TiN on top of the gate contact plug and the source contact plug for providing greater contacting areas to the gate contact plug and the source contact plug. In another preferred embodiment, the method further includes a step of forming a thick front metal layer on top of the resistance-reduction layer for providing a contact layer for a wire or wireless bonding package.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A and 1B are side cross-sectional views of two conventional MOSFET device.

FIG. 2 is a side cross sectional view of a MOSFET device for illustrating a preferred embodiment of this invention.

FIGS. 3A to 3P is a serial of side cross sectional views for showing the processing steps for fabricating a MOSFET device as shown in FIG. 2.

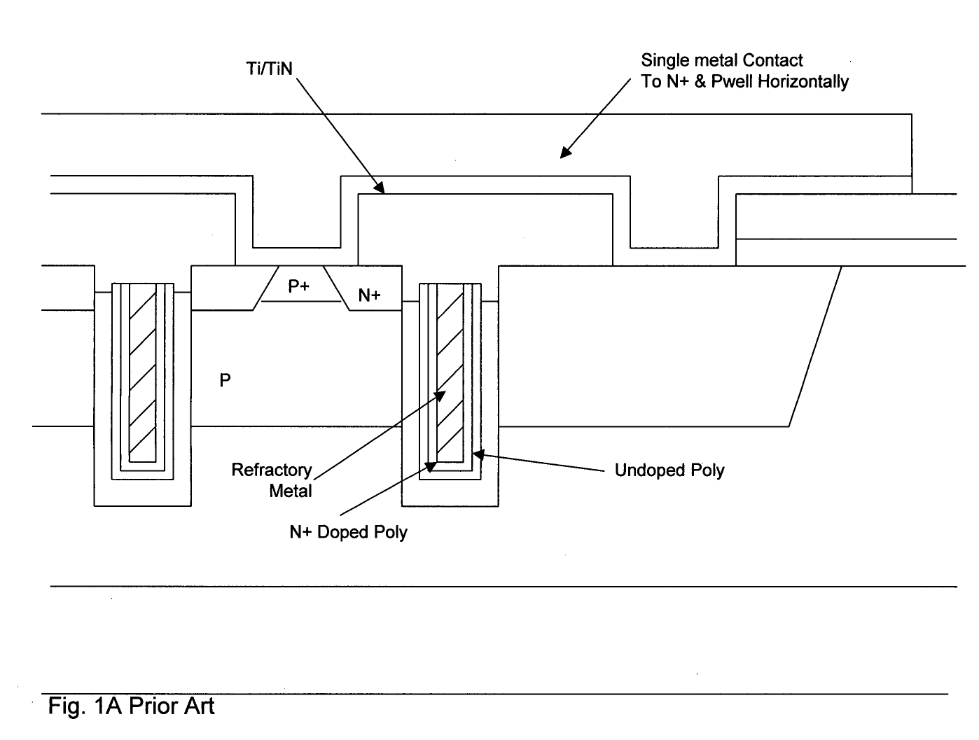

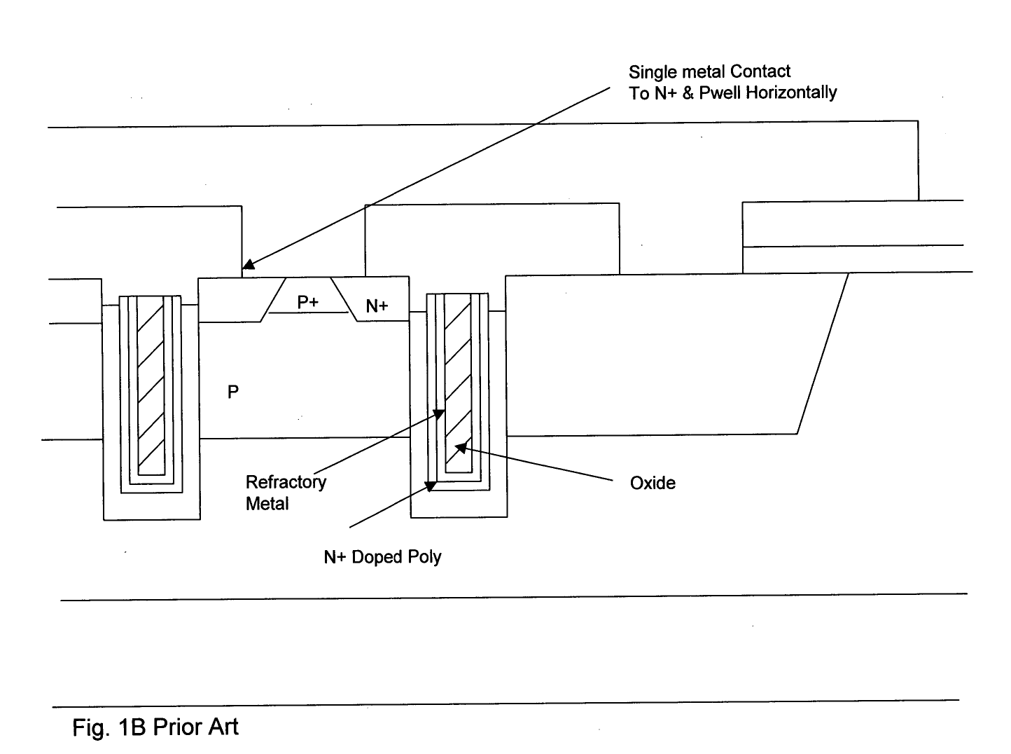

### DETAILED DESCRIPTION OF THE PREFERRED EMBODIMENT

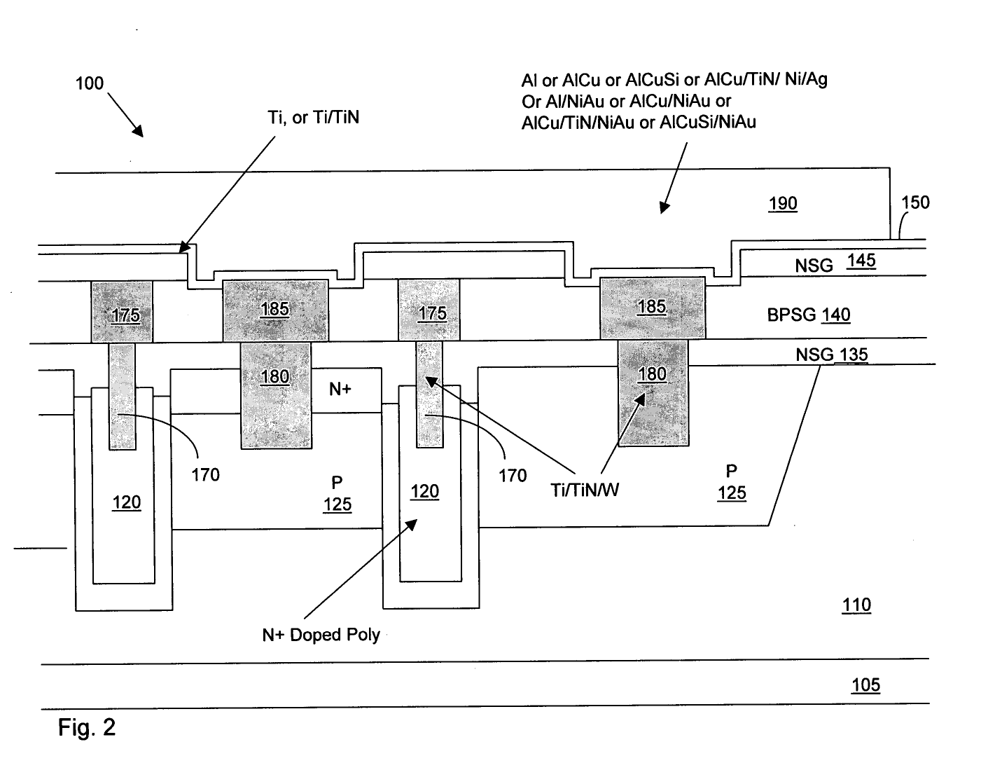

Please refer to FIG. 2 for a cross sectional view of a preferred embodiment of this invention where a metal oxide semiconductor field effect transistor (MOSFET) device 100 is supported on a substrate 105 formed with an epitaxial layer 110. The MOSFET device 100 includes a trenched gate 120 disposed in a trench with a gate insulation layer 115 formed as a linen layer covering the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 125. The top surface of the semiconductor substrate extending over the top of the trenched gate, the P body regions 125 and the source regions 130 are covered with a NSG layer 135, a BPSG protective layers 140 and another insulation NSG layer 145.

The MOSFET device 100 further includes a plurality of gate contact trenches 170 and 175 and source contact trenches 180 and 185. The gate contact trenches 170 and 175 and the source contact trenches 180 and 185 are filled with a barrier layer composed of Ti and TiN and a tungsten plug. As will be shown below the gate contact trenches 170 and 175 and source contact trenches 180 and 185 are formed first with an oxide dry-etch followed by a silicon etch. The oxide etch process opens the trenches that first penetrate through the BPSG layer 140 and the NSG layer 135 to form the upper portion of the trenches 175 and 185. The silicon etch process then opens the trench through the trenched polysilicon gate 170 and the body and source regions 130 and 125 to form the lower portion 170 and 180. The gate contact trenches 170 and 175 and source contact trenches 180 and 185 are then filled with the barrier layer and the tungsten plugs to contact a thin resistance reduction layer 150 composed of Ti or Ti/TiN. As illustrated below, the gate contact trenches 170 and 175 and source contact trenches 180 and 185 are formed in all areas including the active and termination areas to provide good metal step coverage over the contact area with critical dimension (CD) smaller than 0.5 micrometers to save the contact space and to further reduce the gate resistance for the high cell density MOSFET device. By forming these gate contact plugs and the source contact plugs filling in the gate contact trenches 170 and 175 and source contact trenches 180 and 185, there is no need to form the gate runners in the active areas. Furthermore, the P-body regions 125 are formed after the formation of the trench thus the processing sequence of the MOSFET device as disclosed in this invention eliminates the punch-through problem as that often occurs in the conventional MOSFET device.

For the purpose of improving the gate metal contact for reducing the gate resistance and improving the gate contact and also to reduce the source contact area, the gate contact trench 170 and 175 and the source contact trenches 180 and 85 are formed. The gate contact trench 170 and 175 and the source contact trenches 180 and 185 are filled with barrier layer composed of Ti/TiN and tungsten plug wherein the barrier layer composed of Ti/TiN surrounds the tungsten plug.

There are significant differences between the conventional gate runners and gate contact plug and the source contact plug as disclosed in this invention. In the conventional configuration, the gate contact is opened in the oxide layer only. In contrast, the gate contact trench and the source contact trench as shown in FIG. 2 filled with tungsten contact plug are opened through the oxide layer and also the doped polysilicon in the trenched gates and also into the body source regions formed in the silicon substrate. Better electrical contacts are established. The gate contact of the conventional gate is filled with a single metal such as aluminum. The aluminum metal is sputtered into the gate contact openings that often develop a void while the gate contact plugs and source contact plugs of this invention are tungsten plugs. The tungsten plugs are formed with the chemical vapor deposition (CVD) process and the chemical vapor has much better filling characteristics to fill the narrow and deep contact openings without development of void. The CVD process is suitable for process of circuits with critical dimension (CD) less than 0.4 micrometer (μms) in the semiconductor industries. In the conventional MOSFET device, the gate runner for direct contact with a gate contact metal to the gate runners requires a trench width greater than the gate trenches. In contrast, in this invention, the gate contact plug formed in the gate contact trench and the source contact plug formed in the source contact trench may be opened with a trench width same as a gate trench 120. Therefore, the better gate contact with lower gate resistance can be achieved without the required gate runners and without requiring increased gate contact dimension. The source contact trench filled with source contact plug further reduces the space required for the source contact.

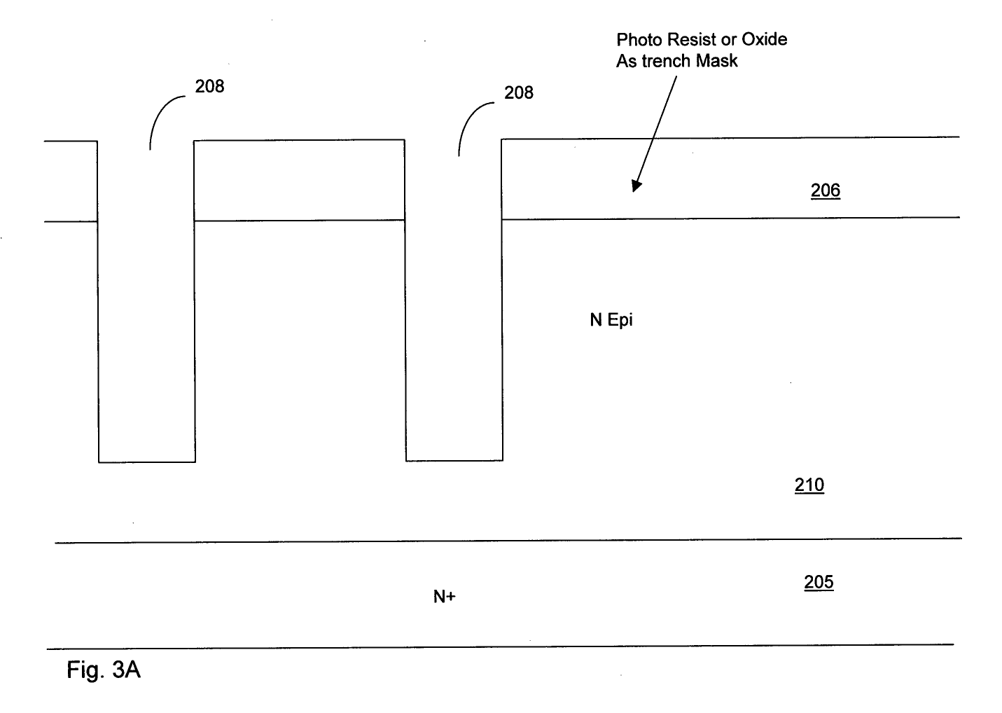

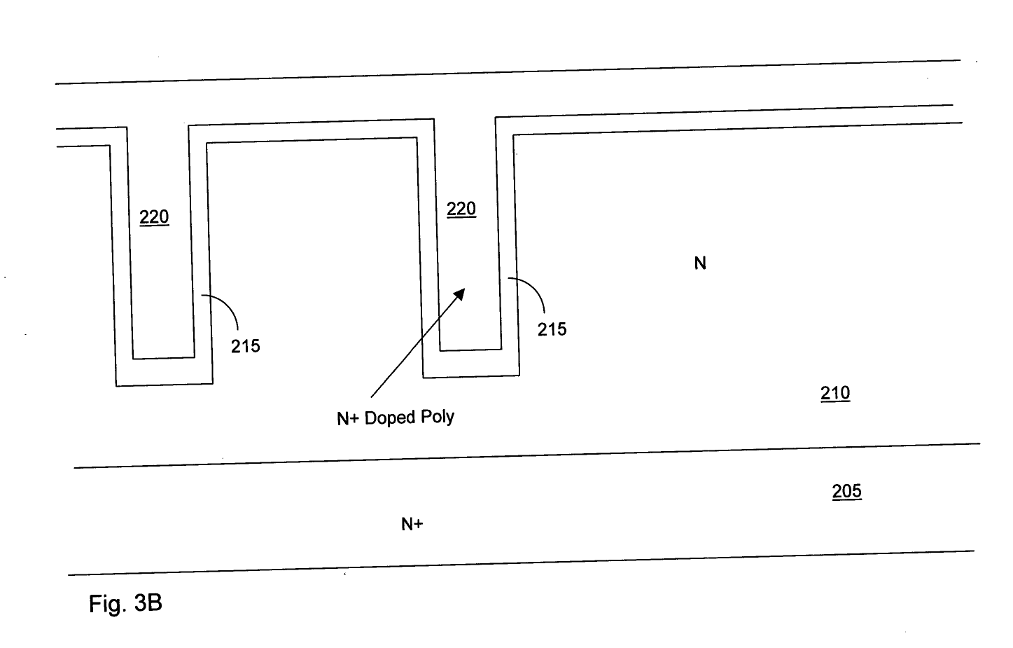

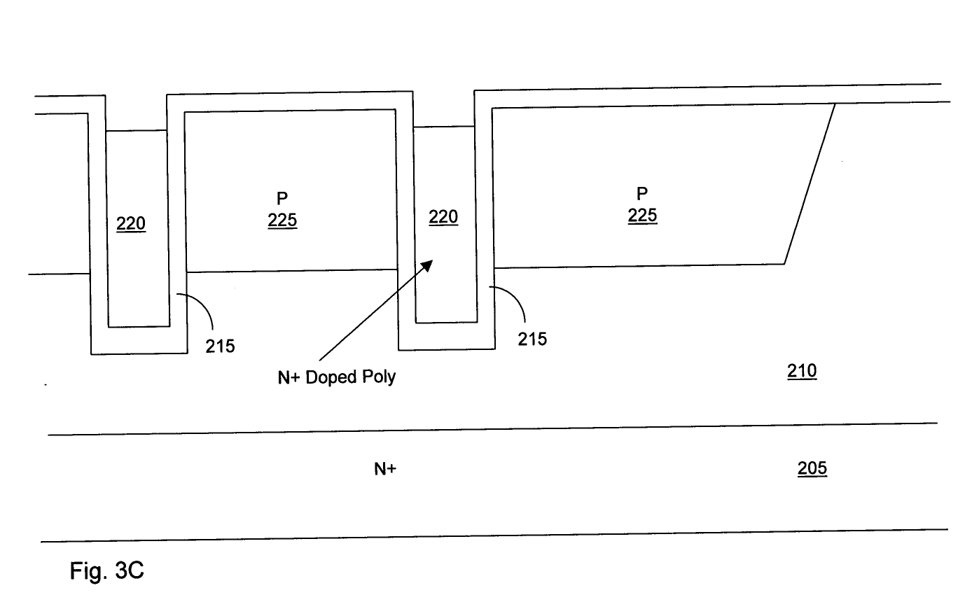

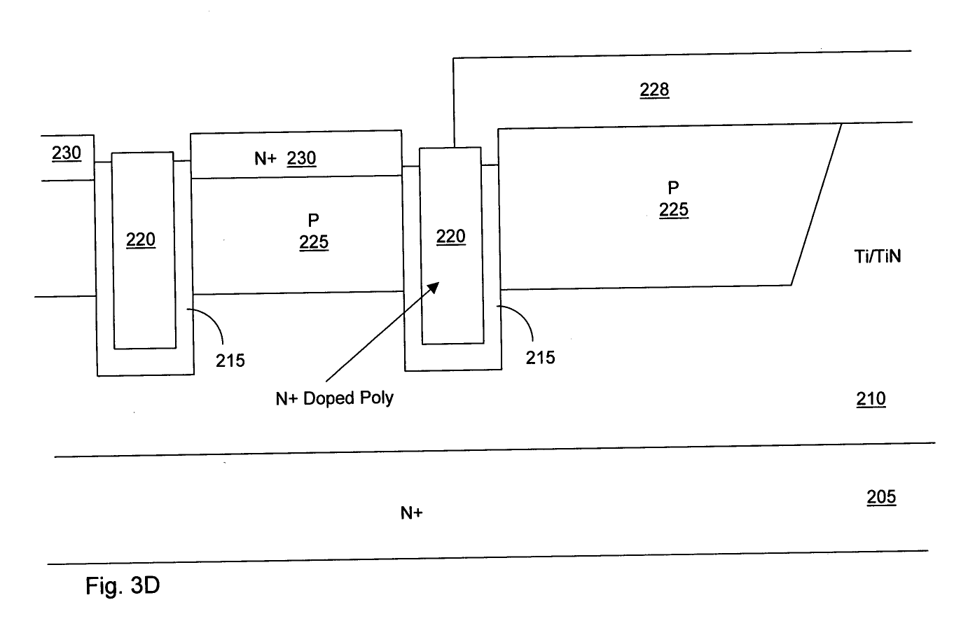

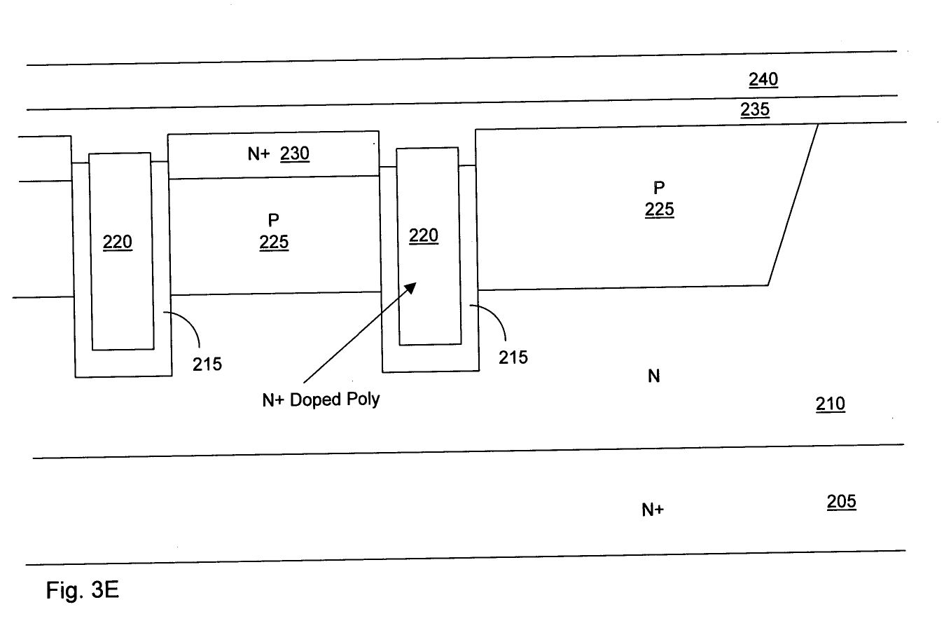

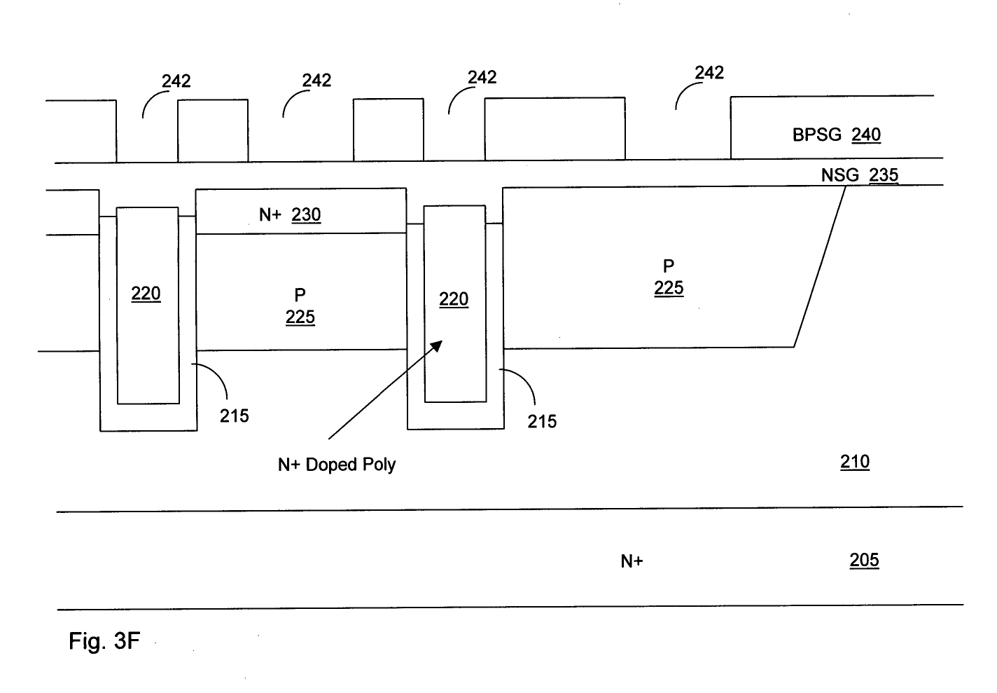

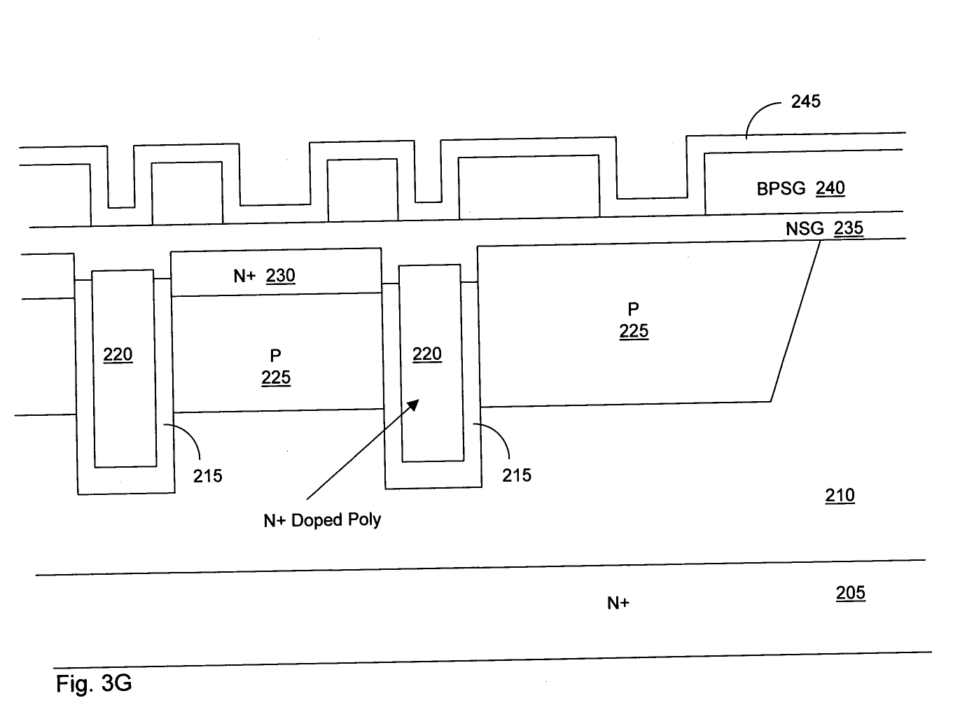

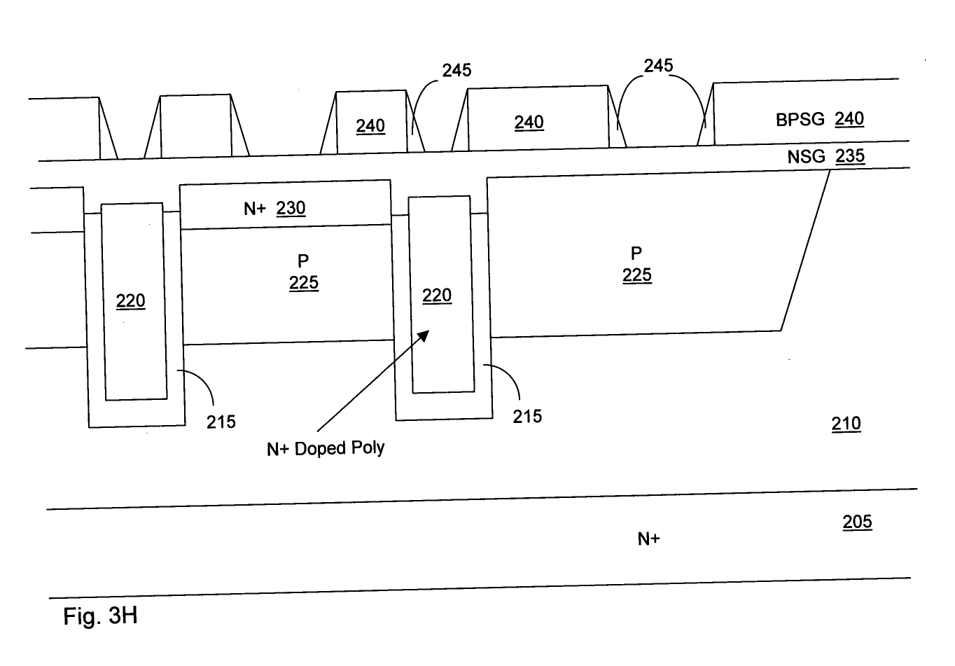

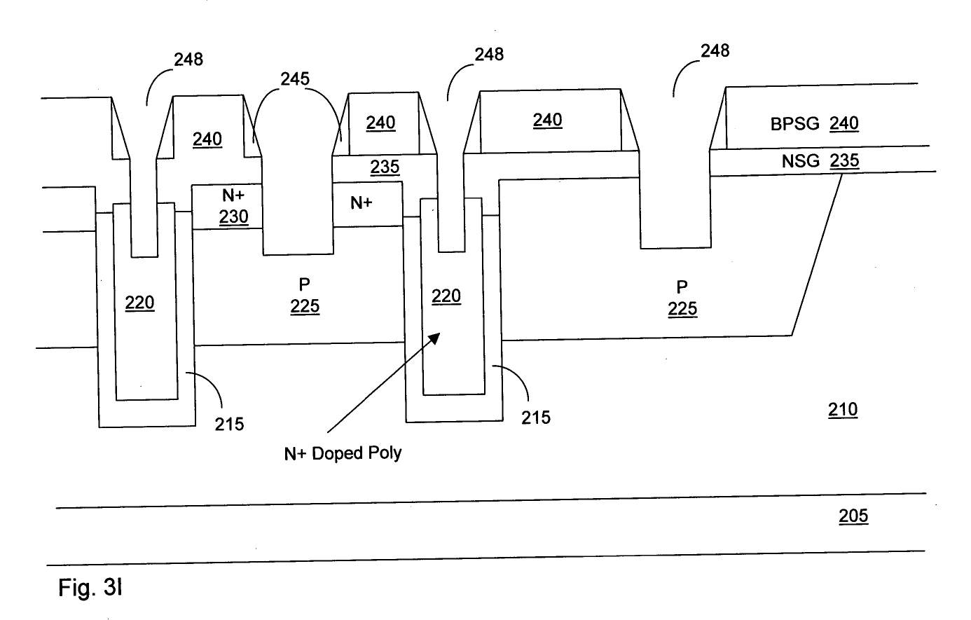

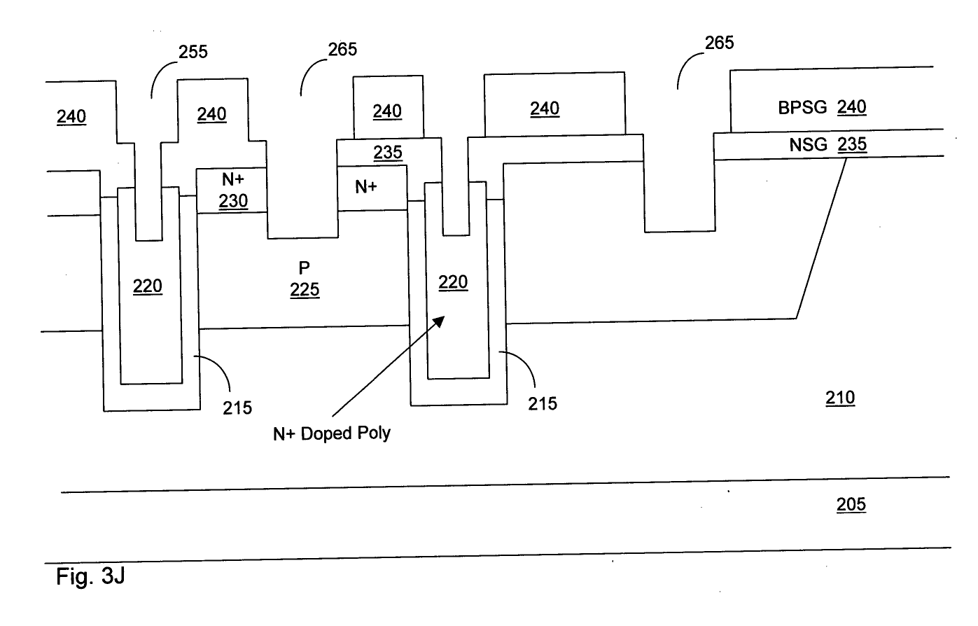

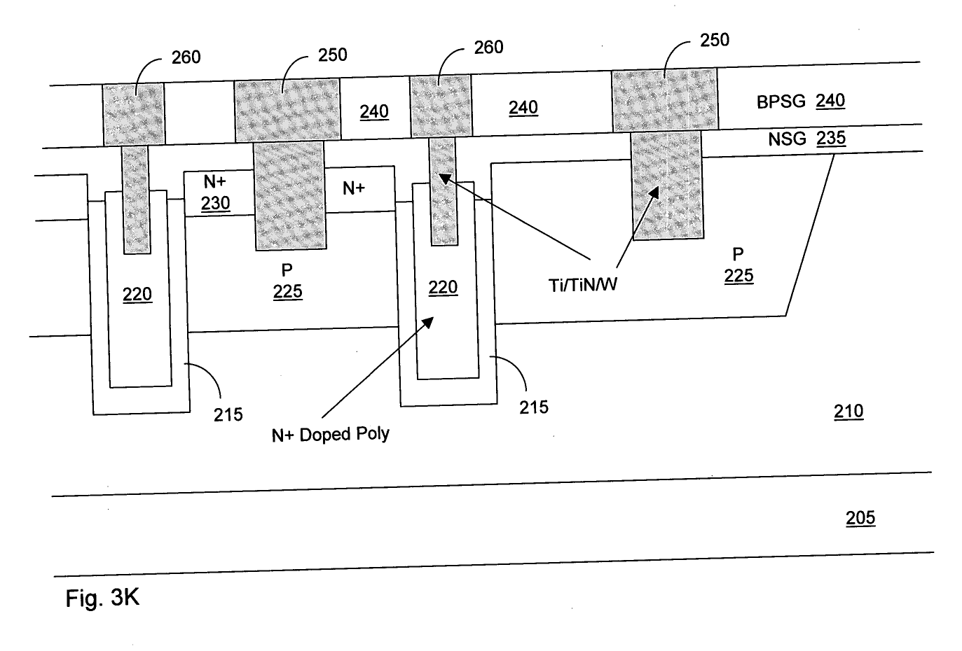

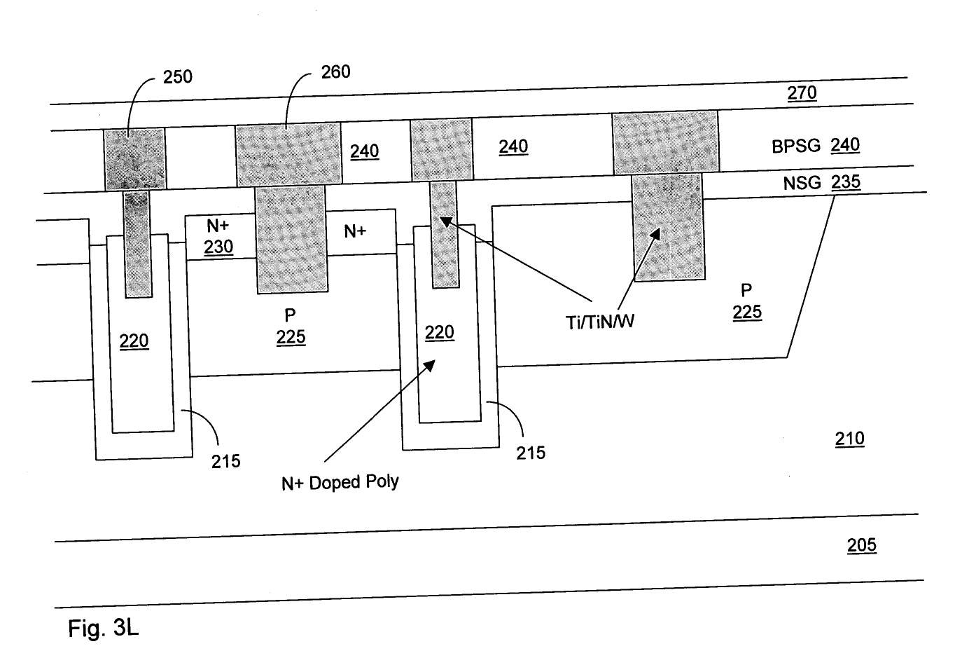

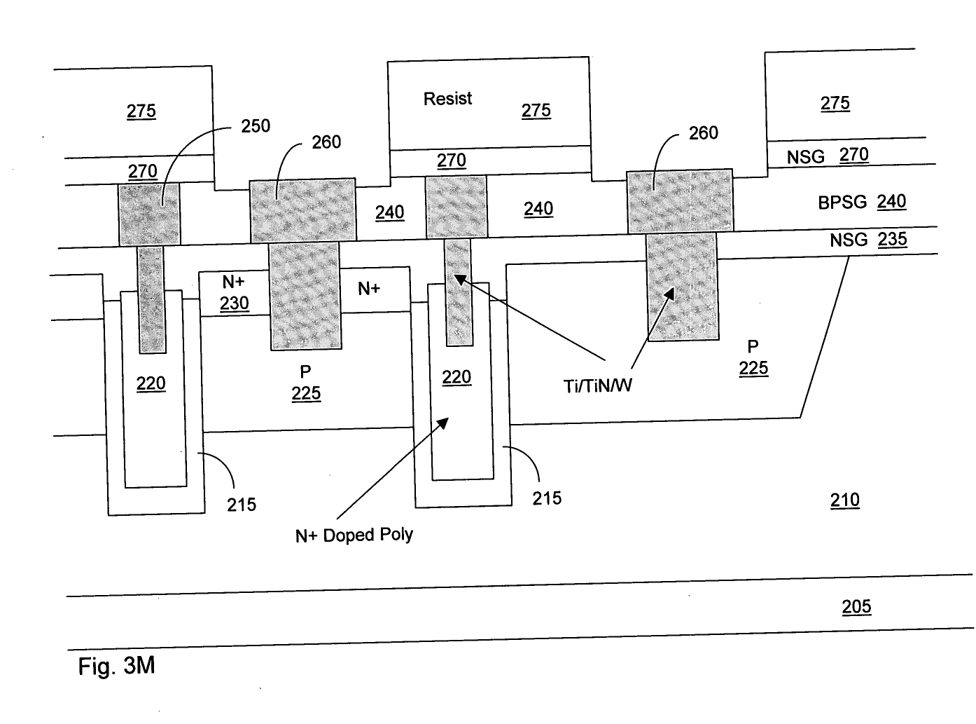

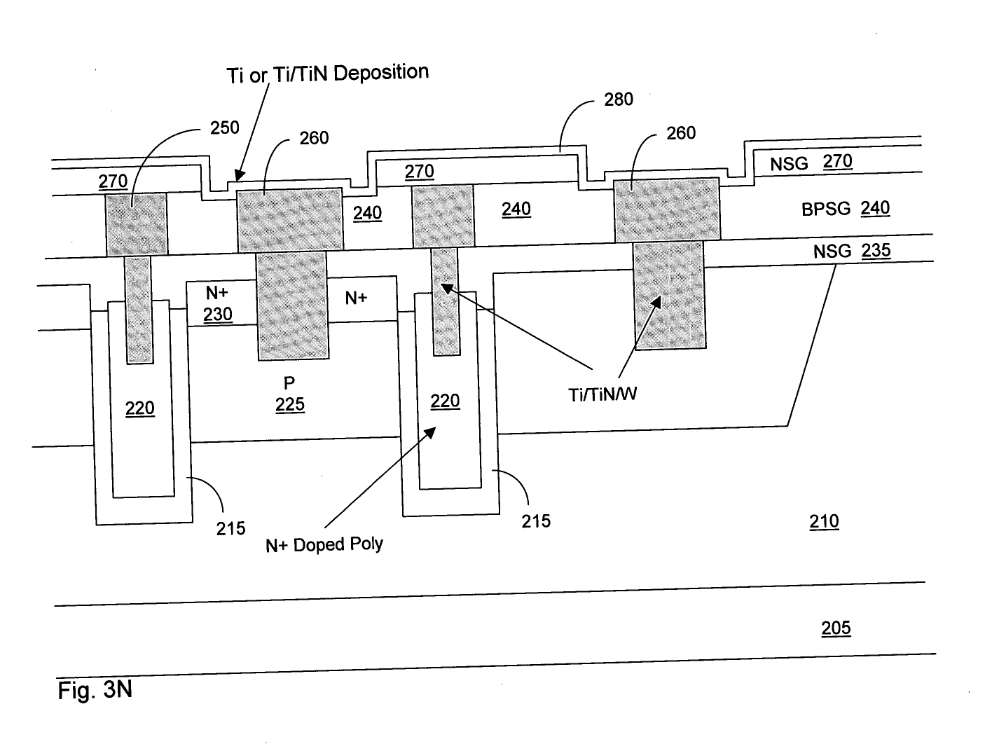

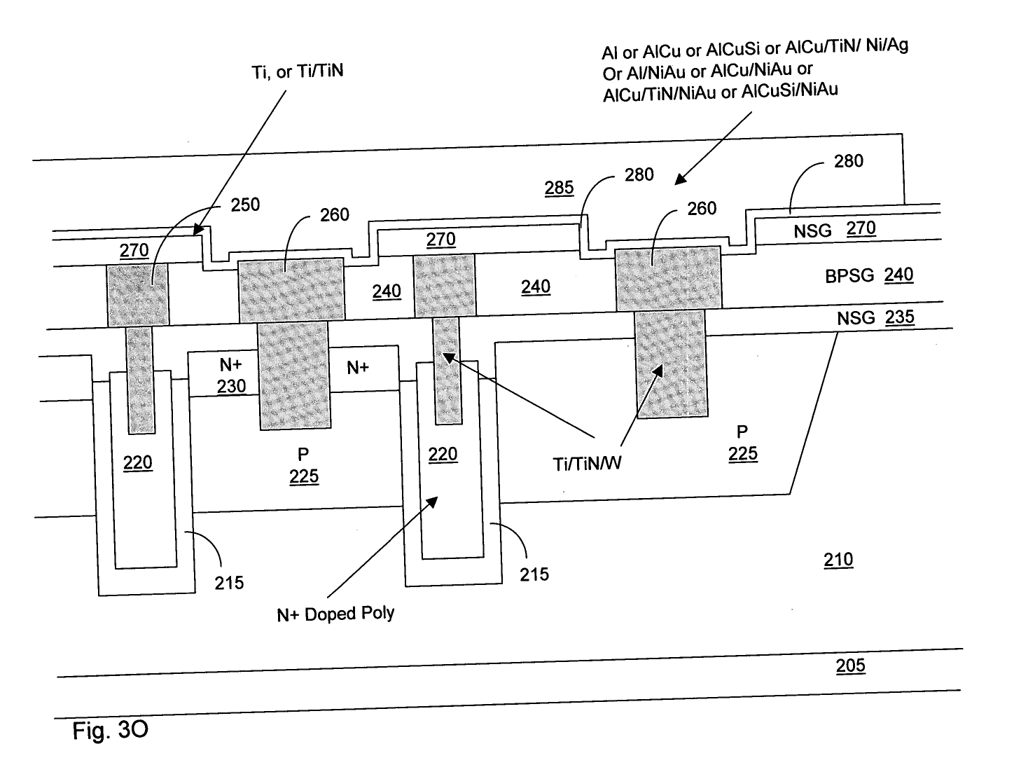

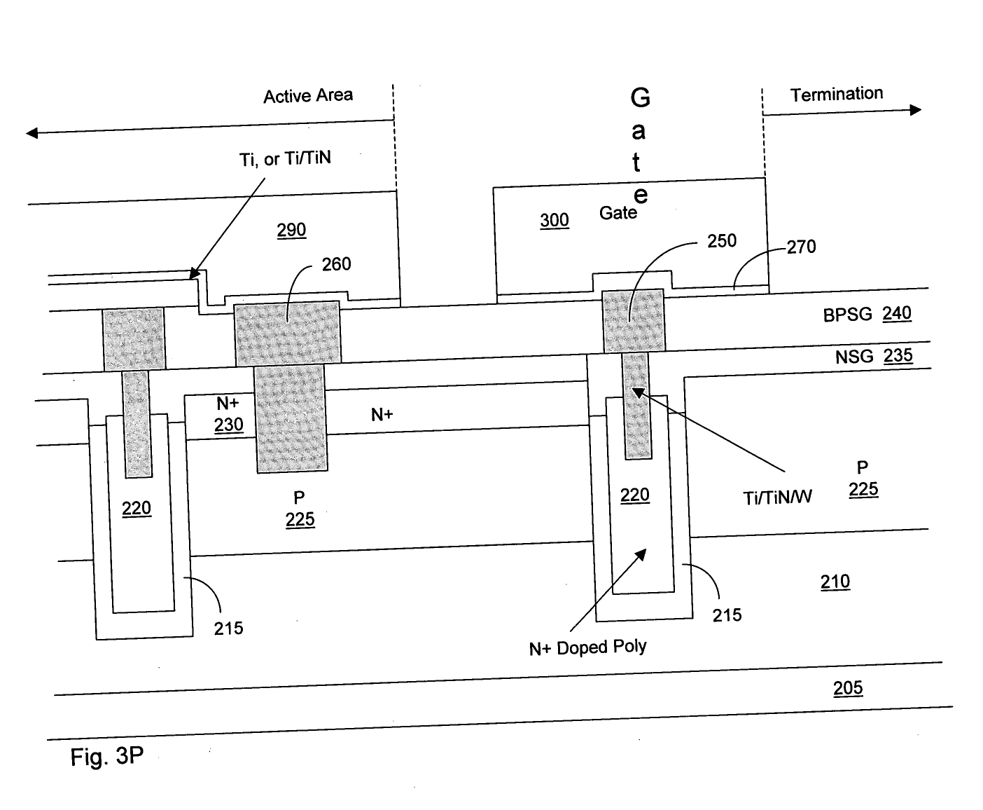

Referring to FIGS. 3A to 3P for a serial of side cross sectional views to illustrate the fabrication steps of a MOSFET device as that shown in FIG. 2. In FIG. 3A, a photoresist or oxide layer 206 is applied to open a plurality of trenches 208 in an epitaxial layer 210 supported on a substrate 205. In FIG. 3B, an oxidation process is performed to form an oxide layer covering the trench walls. The trench 208 is oxidized with a sacrificial oxide to remove the plasma damaged silicon layer during the process of opening the trench. Then an oxide layer 215 is formed followed by depositing a polysilicon layer 220 to fill the trench and covering the top surface and then doped with an N+ dopant. In FIG. 3C, the polysilicon layer 220 is etched back followed by a P-body implant with a P-type dopant. Then an elevated temperature is applied to diffuse the P-body 225 into the epitaxial layer 210. In FIG. 3D, a source mask 228 is applied followed by a source implant with a N-type dopant. Then an elevated temperature is applied to diffusion the source regions 230. In FIG. 3E, a non-doped oxide (NSG) layer 235 and a BPSG layer 240 are deposited on the top surface. In FIG. 3F, a contact mask (not shown) is applied to carry out a contact etch to open the contact openings 242 by applying an oxide etch through the BPSG layer 240. In FIG. 3G, a low pressure chemical vapor deposition (LPCVD) of a nitride layer or a TEOS oxide (CVD oxide from Tetraethoxysilane) layer 245 is deposited on top. In FIG. 3H, a dry etching is carried out to remove the LPCVD or TEOS layer 245 except the nitride or oxide spacers remain surrounding the BPSG segments 240. In FIG. 3I, dry oxide etch is first carried out to etch through the NSG layer 235 followed by a silicon etch to etching into the gate polysilicon 220 and the body regions 225 in the epitaxial layer 210 to form a funnel-shaped trench 248 with a broad top and a narrow-bottom. In FIG. 3J, a nitride layer removal process is carried out to remove the nitride spacer thus forming the gap contact plug trenches 255 and the source contact plug trenches 265 with each of these plug trenches having a stepwise shaped sidewalls having a broader top opening and a narrower bottom opening. In FIG. 3K, each of these plug trenches, i.e., gate contact plug trench 255 and source contact plug trench 265, is then filled with a contact plug, i.e., gate contact plugs 250 and source contact plug 260 wherein each of these contact plugs is composed of Ti/TiN/W. Then an etch-back process is carried out to remove the Ti/TiN/W from the top of the contact plug trenches. In FIG. 3L, another NSG layer 270 is formed on top of the device. In FIG. 3M, an inter-metal dielectric mask 275 is applied to apply a dry oxide etch to remove the NSG layer 270 from the top of the source contact plug 260. Then in FIG. 3N, the photoresist layer 275 is removed and a resistance reduction layer 280 composed of Ti or Ti/TiN is deposited on top to contact the source contact plug 260. In FIG. 30, source and gate contact metal layer 285 is formed. The metal contact layer 285 may be composed of Aluminum (Al), AlCu, AlCu/TiN/Ni/Ag, Al/NiAu, AlCu/NiAu, AlCu/TiN/NiAu, AlCuSi/NiAu. In FIG. 3P, the contact metal is patterned to form source metal contact 290 contact directly to the source contact plug 260 and gate metal contact 300 electrically connecting to the gate through the gate contact plug 250.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A trenched metal oxide semiconductor field effect transistor (MOSFET) device comprising a trenched gate surrounded by a source region encompassed in a body region above a drain region disposed on a bottom surface of a substrate, wherein said MOSFET cell further comprising:
at least two contact trenches opened through an insulation layer covering said MOSFET device wherein said contact trenches extending into said trenched gate and said body region and filled with a gate contact plug and a source contact plug for electrically contact respectively to a gate metal and a source metal disposed on top of said insulation layer.

2. The trenched MOSFET device of claim 1 wherein:
said gate contact trench and source contact trench filled with a Ti/TiN barrier layer and a tungsten plug to form said gate contact plug and said source contact plug.

3. The trenched MOSFET device of claim 1 wherein:
said gate contact trench is opened through an oxide layer as said insulation layer and penetrating into said trenched gate filled with a gate polysilicon; and
said source contact trench is opened through said oxide layer as said insulation layer and penetrating into said body region composed of a doped silicon disposed near a top surface of said substrate.

4. The trenched MOSFET device of claim 1 wherein:
said gate contact trench and said source contact trench are opened by a dry oxide etch process followed by a silicon etch to form substantially vertical trenches to extend to said trenched gate and said body region.

5. The trenched MOSFET device of claim 1 wherein:
said gate contact trench and said source contact trench are opened by a dry oxide etch process followed by a silicon etch to form substantially vertical trenches with stepwise side walls to extend to said trenched gate and said body region.

6. The trenched MOSFET device of claim 1 wherein:
said gate contact trench and said source contact trench are opened by a dry oxide etch process followed by a silicon etch to form trenches with sloped side walls to extend to said trenched gate and said body region.

7. The trenched MOSFET device of claim 1 wherein:
said gate contact trench and said source contact trench are opened by a dry oxide etch process with an nitride spacer followed by a silicon etch to form substantially champagne-cup shaped trenches with stepwise side walls to extend to said trenched gate and said body region.

8. The trenched MOSFET device of claim 1 wherein:
said gate contact plug electrically contacting said trenched gate via a bottom portion of said gate contact plug contact said trenched gate and said source contact plug electrically contacting said source region via side-walls of said source contact trench extending into said body region.

9. The trenched MOSFET device of claim 1 wherein:
said gate contact plug electrically contacting side walls of said gate contact trench extending into said trenched gate.

10. The trenched MOSFET device of claim 1 further comprising:
a thin resistance reduction layer formed on top of said gate contact plug and said source contact plug for providing greater contacting areas to said gate contact plug and said source contact plug.

11. The trenched MOSFET device of claim 1 further comprising:
a thin resistance reduction layer composed of Ti disposed on top of said gate contact plug and said source contact plug for providing greater contacting areas to said gate contact plug and said source contact plug.

12. The trenched MOSFET device of claim 1 further comprising:
a thin resistance reduction layer composed of Ti/TiN disposed on top of said gate contact plug and said source contact plug for providing greater contacting areas to said gate contact plug and said source contact plug.

13. The trenched MOSFET device of claim 12 further comprising:
a thick front metal layer disposed on top of said resistance-reduction layer for providing a contact layer for a wire or wireless bonding package.

14. The trenched MOSFET device of claim 13 wherein:
said front thick metal layer comprising an aluminum layer.

15. The trenched MOSFET device of claim 13 wherein:
said front thick metal layer comprising an AlCu layer.

16. The trenched MOSFET device of claim 13 wherein:
said front thick metal layer comprising an AlCuSi layer.

17. The trenched MOSFET device of claim 13 wherein:
said front thick metal layer comprising an Al/NiAu layer.

18. The trenched MOSFET device of claim 13 wherein:
said front thick metal layer comprising an AlCu/NiAu layer.

19. The trenched MOSFET device of claim 13 wherein:
said front thick metal layer comprising an AlCuSi/NiAu layer.

20. The trenched MOSFET device of claim 13 wherein:
said front thick metal layer comprising an NiAg layer.

21. The trenched MOSFET device of claim 13 wherein:
said front thick metal layer comprising an NiAu layer.

22. The trenched MOSFET device of claim 1 wherein:
said MOSFET cell further comprising a N-channel MOSFET cell.

23. The trenched MOSFET device of claim 1 wherein:
said MOSFET cell further comprising a P-channel MOSFET cell.

24. A method for manufacturing a trenched metal oxide semiconductor field effect transistor (MOSFET) device comprising:
opening at least two contact trenches through an insulation layer covering said MOSFET device and extending said contact trenches into a trenched gate and a body region followed by filling said contact trenches with a gate contact plug and a source contact plug for electrically contacting respectively to a gate metal and a source metal disposed on top of said insulation layer.

25. The method of claim 24 wherein:
said step of filling said contact trenches further comprising a step of filling said gate contact trench and source contact trench with a Ti/TiN barrier layer and a tungsten plug to form said gate contact plug and said source contact plug.

26. The method of claim 24 wherein:
said step of opening said contact trenches further comprising a step of opening a gate contact trench through an oxide layer as said insulation layer for penetrating into a gate polysilicon filled in said trenched gate; and
said step of opening said contact trenches further comprising a step of opening a source contact trench is through said oxide layer as said insulation layer for penetrating into said body region composed of a doped silicon disposed near a top surface of said substrate.

27. The method of claim 26 wherein:
said step of opening said gate contact trench and said source contact trench further comprising a step of applying a dry oxide etch process followed by a silicon etch to form substantially vertical trenches to extend to said trenched gate and said body region.

28. The method of claim 26 wherein:
said step of opening said gate contact trench and said source contact trench further comprising a step of applying a dry oxide etch process followed by a silicon etch to form substantially vertical trenches with stepwise side walls to extend to said trenched gate and said body region.

29. The method of claim 26 wherein:
said step of opening said gate contact trench and said source contact trench further comprising a step of applying a dry oxide etch process followed by a silicon etch to form trenches with sloped side walls to extend to said trenched gate and said body region.

30. The method of claim 26 wherein:
said step of opening said gate contact trench and said source contact trench further comprising a step of applying a dry oxide etch process with an nitride spacer followed by a silicon etch to form substantially champagne-cup shaped trenches with stepwise side walls to extend to said trenched gate and said body region.

31. The method of claim 24 wherein:
said step of filling contact trenches with said gate contact plug for electrically contacting said trenched gate further comprising a step of filling said contact trenches with said gate contact plug for electrically contacting said trenched gate via a bottom portion of said gate contact plug and said step of filling contact trenches with said source contact plug for electrically contacting said source further comprising a step of filling said contact trenches with said source contact plug for electrically contacting said source via side-walls of said source contact trench extending into said body region.

32. The method of claim 24 wherein:
said step of filling said contact trenches with said gate contact plug further comprising a step of filling said gate contact plug to extend into said trench gate for electrically contacting said gated trench via side walls of said gate contact trench extending into said trenched gate.

33. The method of claim 24 further comprising:
forming a thin resistance reduction layer on top of said gate contact plug and said source contact plug for providing greater contacting areas to said gate contact plug and said source contact plug.

34. The method of claim 24 further comprising:
forming a thin resistance reduction layer composed of Ti on top of said gate contact plug and said source contact plug for providing greater contacting areas to said gate contact plug and said source contact plug.

35. The method of claim 24 further comprising:
forming a thin resistance reduction layer composed of Ti/TiN on top of said gate contact plug and said source contact plug for providing greater contacting areas to said gate contact plug and said source contact plug.

36. The method of claim 33 further comprising:
forming a thick front metal layer on top of said resistance-reduction layer for providing a contact layer for a wire or wireless bonding package.
